(19) United States
(12) Patent Application Publication
(10) Pub. No.: US 2008/0308291 A1
(43) Pub. Date: Dec. 18, 2008

(54) Safety filler plug for recessed electrical contacts

(76) Inventors: Robert A. Libby, Williamsport, PA (US); Charles A. Libby, II, Montoursville, PA (US); David E. Montgomery, Montoursville, PA (US); Kyle Mason, Williamsport, PA (US)

Correspondence Address: Thomas R Shaffer;Glassmire & Shaffer Law Offices, P.C., 5 East Third Street, Coudersport, PA, 16915, US

(21) Appl. No.: 11/818,758

(22) Filed: Jun. 15, 2007

(51) Int. Cl. H05K 5/03

(52) U.S. Cl. 174/66

(57) ABSTRACT

A safety filler plug for recessed electrical contacts is provided. The plug includes a pair of spaced apart generally rectangular arm members including a first stationary arm member and a second tab arm member. The first arm member and the second arm member each have an insertion end, an extension end and a middle portion between the insertion end and said extension end. A generally rectangular horizontal barrier member extends between and bridges the middle portions of arm members. The barrier member has an interior surface and exterior surface. A cross bar support member extends between and has cross bar end portions connected to the insertion ends of the arms. A generally triangular brace member having a first side portion connected to the first arm member and a second side portion connected to said exterior surface of said barrier member is also provided.

### BACKGROUND OF THE INVENTION

1. Field of the Invention

The present invention relates to a fitting for an electrical box or an enclosure. More specifically, it relates to a manufactured plastic plug for the purpose of filling in a cavity or port in a manufactured wiring device where exposure to energized contacts or conductors could occur.

2. Description of the Prior Art

The purpose of a filler or filler plug is to occupy a port or opening that may expose electrical contacts. In particular, the present invention relates to electrical boxes and electrical enclosures where knockouts are provided. An example of this hole or knockout is in an electrical junction box where a wire is intended to enter the box such as that shown in FIG. 6. If an electrical contractor or installer would inadvertently remove a knockout (105) and then decide he was not going to use that hole, he is then required to fill that opening. This would be accomplished by a filler plug of any of a variety of known types. An example of this type plug used to fill this hole would be shown in the Sampson, U.S. Pat. No. 3,072,287, in FIGS. 2-6. Several other types of filler plugs are shown in Thomas, Jr., U.S. Pat. No. 1,491,325 (FIGS. 1-2); Sims, U.S. Pat. No. 5,339,491 (FIGS. 1-2); and Ehrenfels, U.S. Pat. No. 5,434,360 (FIG. 4).

A number of patents provide for safety plugs for duplex receptacles. For example Erdfard, U.S. Pat. No. 6,103,974 and Howe, Jr., U.S. Pat. No. 6,664,471 each provide a plate member which covers the entire front of the receptacle box. Howe, Jr. utilizes prongs 38 which stick into the outlet receptacle slots 16 and Erdfarb utilizes arms or tabs 27 to provide a frictional engagement to secure the cover in place.

Nichols, U.S. Pat. No. 6,051,788 teaches the provision of a receptacle cover plate which has a depth of ½ inch which provides a pair of plug passages 22 into which plugs 24, 34, or 46 are inserted which the outlet is not being used.

Murr et al., U.S. Pat. No. 6,927,339, discloses a cover for electronic components provided for assisting a tool in assembling the electrical component to another structure. The device includes a body section which is adapted to form a vacuum seal with a tool and a component retention member connected to the body for releasably connecting the body to an electrical component.

Finally, Arnett, U.S. Pat. No. 5,096,439 provides a wall plate having jack release slots which utilize a dust cover 90 (FIG. 4).

### SUMMARY OF THE INVENTION

The present invention is specifically adapted for use with the Q-CEB (Quick Connect Electrical Box) line of electrical products from Aslan Industries Corporation of Montoursville, Pa. Some of the Q-CEB products are shown in FIG. 3, namely, a coupling (FIG. 3a), a junction box (FIG. 3b) and another style junction box (FIG. 3c). A switch and a receptacle are shown in FIGS. 2a and 2b, respectively. These products are described in detail in Libby, II et al., U.S. Pat. No. 7,204,696 and Libby, II, U.S. Pat. No. 7,211,751.

Another product is represented in Libby, U.S. Pat. Nos. 7,144,269 and 5,975,938, shown as 100 in FIGS. 4a & 4d. This device is an insulation displacement connector (IDC). The connector terminates an electrical cable to the devices previously mentioned. This connector plugs into a recess or port where male pins accept the connector for electrical termination.

Every Q-CEB electrical device has at least one port 101. FIG. 2c, the back side of the switch and receptacle and FIGS. 3a, 3b, & 3c illustrates these ports. The ports are designed specifically to accept the Q-CEB (IDC) connector. Some wiring devices have more than one port and are used when certain wiring applications of a circuit are required. There are some applications where only a few of the ports will be used leaving unused parts open and exposed. In these applications it is necessary to fill or cover the open port for electrical safety reasons.

The present invention provides a high strength insulating plastic filler plug having a generally “H” shaped configuration which will accomplish this purpose in a manner which provides for easy insertion, easy removal, secure anchoring to the port (to prevent unwanted or accidental removal) and which has a low cost of manufacture.

### BRIEF DESCRIPTION OF THE FIGURES

FIGS. 1a, 1b and 1c are perspective views of the safety filler plug of the present invention.

FIG. 2a is a front perspective view of a switch box having/utilizing a toggle switch.

FIG. is 2b a front perspective view of a duplex receptacle box.

FIG. 2c is a rear perspective view showing the configuration of the rear sides of each of the switch box of FIG. 2a and the receptacle box of FIG. 2b.

FIG. 3a is a perspective view of a coupling device for use with a quick connect electrical connector.

FIG. 3b is a perspective view of a junction box for easily joining and connecting multiple quick connect electrical connectors together.

FIG. 3c is a perspective view of an alternative style of junction box for easily joining and connecting multiple quick connect electrical connectors together.

FIG. 4a is a perspective view of the junction box of FIG. 3b having a quick connect electrical connecter inserted in a port thereof.

FIG. 4b is a perspective view of the junction box of FIG. 3b having a safety filler plug positioned for insertion into a port thereof.

FIG. 4c is a perspective view of the junction box of FIG. 3b having a safety filler plug inserted in a port thereof.

FIG. 4d is a perspective view of a quick connect electrical connector as connected to an unstripped end of an insulated electrical cable.

FIG. 5 is a cross-sectional view of a portion of a port showing a notch as received by a latch portion of a safety filler plug of the present invention.

FIG. 6 is a perspective view of a prior art junction box having plural knock out plugs.

### DETAILED DESCRIPTION OF THE PREFERRED EMBODIMENTS

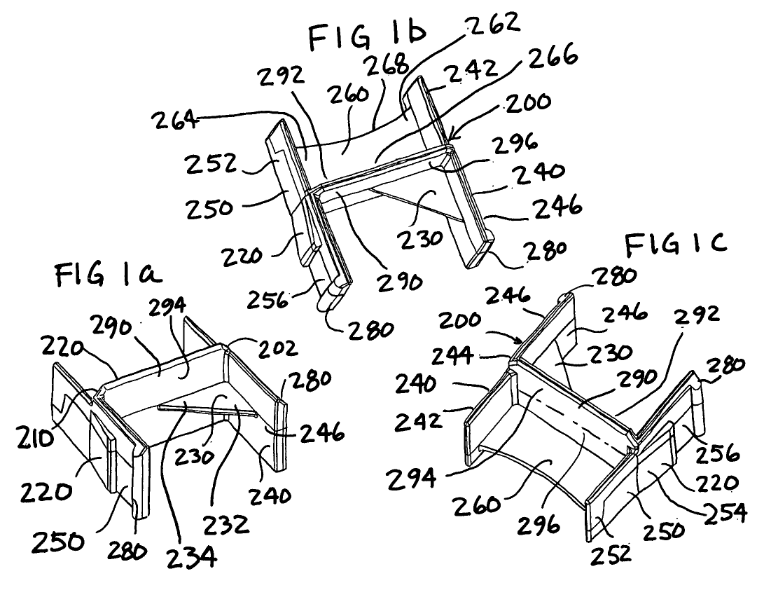

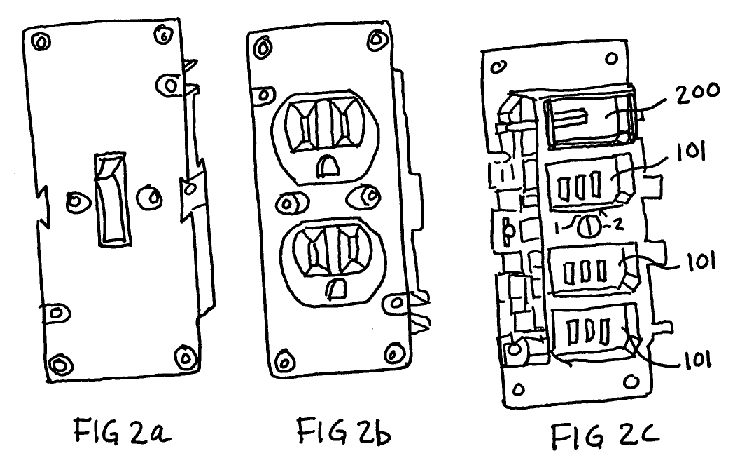

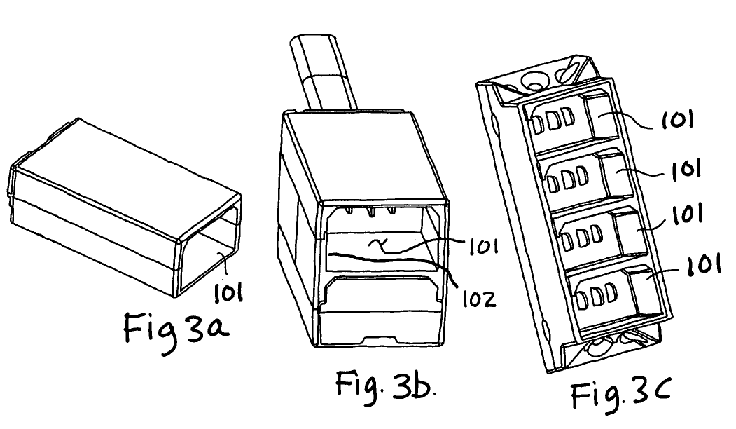

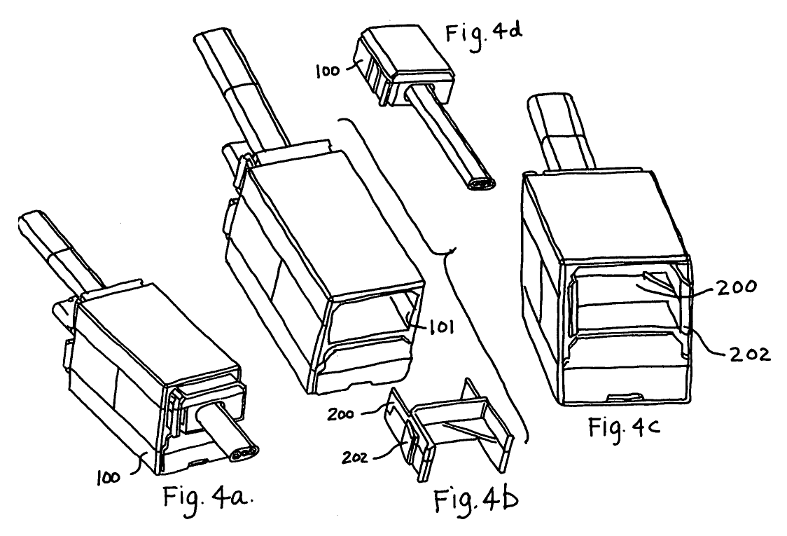

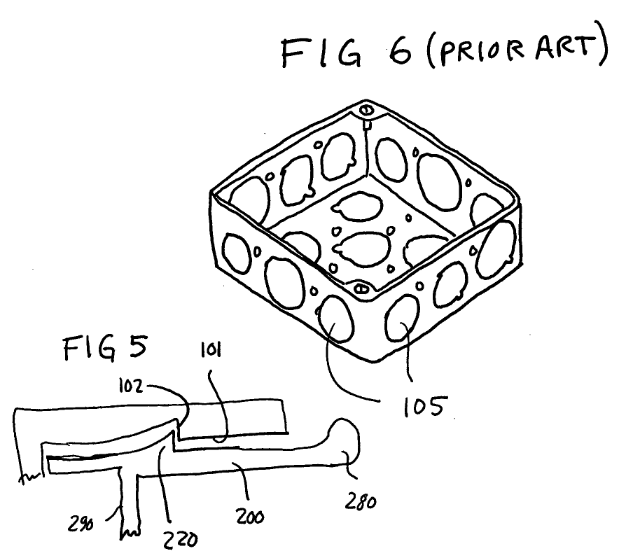

FIGS. 1a, 1b, 1c show three perspective views of the safety plug 200 of the present invention. The invention is called the “H-Filler” because it looks like the letter H. The angle or chamfer 210, on the top side 202 of the plug 200 is a feature designed so it will only enter the port in one specific manner. This allows the release tab 220 to always align itself on the side that will “catch” the tab and hold the H-Filler in place (FIG. 5). The angled brace or gusset 230, strengthens and supports the stationary arm 240 giving the release tab arm 250 the ability to flex inward and back for the purpose of latching and releasing the plug enabling withdrawal. The cross bar support 260 which is shown in the form of an arc bracing is designed to strengthen the inner portion or insertion ends 242, 254 of arms 240, 250, respectively, and keep them from flexing outward, scraping the walls of the port, allowing for ease in retracting the filler plug. Finger tabs 280 are provided on extension ends 246, 256 of arms 240, 250, respectively. Finger tabs 280 allow the installer to easily grasp the plug and push it into the port or squeeze the tab and remove the filler from the port if desired. FIG. 4c shows the H-Filler plug inserted in a port of a Q-CEB junction box, closing and sealing the port. FIG. 2c illustrates how the Filler plug is used in the back side of either the receptacle or the switch.

A generally rectangular horizontal barrier member 290 extends between and bridges middle portions 244, 254 of arm members 240, 250, respectively. The barrier member 290 has an interior surface 292 and exterior surface 294.

The present invention, in its simplest form provides a safety filler plug 200 for recessed electrical contacts 101 having a pair of spaced apart generally rectangular arm members including a first stationary arm member 240 and a second tab arm member 250, said first arm member 240 and said second arm member 250 each having an insertion end 242, 252, an extension end 246, 256 and a middle portion 244, 254 between said insertion end and said extension end. A generally rectangular horizontal barrier member 290 extends between and bridges said middle portions 244, 254 of arm members 240, 250, respectively. The barrier member 290 has an interior surface 292 and exterior surface 294.

A cross bar support member 260 extends between and has cross bar end portions 262, 264 connected to said insertion ends 242, 252 of said first arm member 240 and said second arm member 250. The cross bar support member 260 has a cross bar side portion 266 connected to said interior surface 292 of said barrier member 290.

A generally triangular brace member 230 having a first side portion 232 connected to said first arm member and a second side portion 234 connected to said exterior surface 294 of said barrier member 290. With this triangular brace member 230 in place, the second arm member 250 is more flexible than said first arm member 240. As shown, the second leg member 250 does not contact said triangular brace member 230. As indicated above the second arm member 250 has a latch portion 220 provided on said extension end 256 thereof.

The cross bar support member 260 extends between the insertion ends 242, 262 of said first arm 240 and said second arm 250. The cross bar support member 260 is generally planar and is situate in a plane which is rotated 90 degrees from said first and said second arm members, 240, 250. The cross bar member 260 is also situate in a plane which is parallel to said triangular brace member 230. As shown in FIG. 1c, the cross bar bracing member 260 is located below a longitudinal mid-line 296 of said horizontal barrier member 290 The innermost portion 268 of the cross bar support 260 is accurate in shape. The triangular brace member 230 is located on a longitudinal mid-line 296 of said horizontal barrier member 290.

In operation, the second arm member 250 has a latch portion 220 provided on said extension end 256 thereof and said extension end 256 of the second arm member 250 can be flexed toward said first arm member 240 to disengage said latch member 220 and remove said plug 200 from a recess 101 containing electrical contacts. This is accomplished by gripping and squeezing together the extension ends 246,256 of said first arm member 240 and said second arm member 250 by gripping finger tab portions 280 thereon. Said finger tabs 280 facilitate gripping and squeezing relatively closer together said extension ends 244, 256 of said first arm member 240 and said second arm member 250 to disengage said latch member 220 and remove said plug 200 from a recess 101 containing electrical contacts. As will be obvious, the latch portion 220 provided on said extension end 256 of said second arm is adapted to be received by a notch 102 provided in a recessed opening 101 of an electrical device.

It is to be understood that while certain forms of the present invention have been illustrated and described herein, the present invention is not to be limited to the specific forms or arrangements of parts described and shown.

We claim:

1. A safety filler plug for recessed electrical contacts comprising of:
a) a pair of spaced apart generally rectangular arm members including a first stationary arm member and a second tab arm member, said first arm member and said second arm member each having an insertion end, an extension end and a middle portion between said insertion end and said extension end;
b) a generally rectangular horizontal barrier member extending between and bridging said middle portions of arm members, said barrier member having an interior surface and exterior surface;
c) a cross bar support member extending between and having cross bar end portions connected to said insertion ends of said first arm member and said second arm member and having a cross bar side portion connected to said interior surface of said barrier member; and
d) a generally triangular brace member having a first side portion connected to said first arm member and a second side portion connected to said exterior surface of said barrier member.

2. A safety filler plug according to claim 1 wherein the second arm member is more flexible than said first arm member.

3. A safety filler plug according to claim 1 wherein the second arm member has a latch portion provided on said extension end thereof.

4. A safety filler plug according to claim 1 wherein said second leg member does not contact said triangular brace member.

5. A safety filler plug according to claim 1 wherein said cross bar support member extends between the insertion ends of said first arm and said second arm.

6. A safety filler plug according to claim 5 wherein said cross bar support member generally planar and is situate in a plane which is rotated 90 degrees from said first and said second arm members.

7. A safety filler plug according to claim 5 wherein said cross bar support member is generally planar and is situate in a plane which is parallel to said triangular brace member.

8. A safety filler plug according to claim 5 wherein said cross bar support member is located below a longitudinal mid-line of said horizontal barrier member.

9. A safety filler plug according to claim 5 wherein said cross bar support member has an innermost portion which is accurate in shape.

10. A safety filler plug according to claim 1 wherein said triangular brace member is located on a longitudinal mid-line of said horizontal barrier member.

11. A safety filler plug according to claim 1 wherein in second arm member has a latch portion provided on said extension end thereof and wherein said extension end of second arm member can be flexed toward said first arm member to disengage said latch member and remove said plug from a recess or port containing electrical contacts.

12. A safety filler plug according to claim 1 wherein said extension ends of said first arm member and said second arm member each have a finger tab portion thereon.

13. A safety filler plug according to claim 12 wherein said finger tabs facilitate gripping and squeezing relatively closer together said extension ends of said first arm member and said second arm member to disengage said latch member and remove said plug from a recess or port containing electrical contacts.

14. A safety filler plug according to claim 1 wherein in second arm member has a latch portion provided on said extension end thereof which is adapted to be received by a notch provided in a recessed opening of an electrical device.
